(19) United States
(12) Patent Application Publication
(10) Pub. No.: US 2020/0256954 A1
(43) Pub. Date: Aug. 13, 2020

(54) OPTICAL PULSE CODING IN A LIDAR SYSTEM

(71) Applicant: Analog Devices, Inc., Norwood, MA (US)

(72) Inventors: Ronald A. Kapusta, Carlisle, MA (US); Shawn S. Kuo, Arlington, MA (US); Miles R. Bennett, Stanford, CA (US)

(21) Appl. No.: 16/270,055

(22) Filed: Feb. 7, 2019

(51) Int. Cl. G01S 7/484; H01S 5/062; G01S 17/10

(52) U.S. Cl. CPC G01S 7/484; G01S 17/10; H01S 5/062

(57) ABSTRACT

Techniques are described to encode a single light pulse with information that can provide the benefits of a single long pulse and a short, coded pulse train. For example, techniques are described to generate a light pulse for transmission that has an optical intensity profile that includes a waveform having one or more relatively narrower pulses superimposed upon a relatively wider pulse. Thus, a hybrid pulse can be generated that includes both a wide pulse and a narrow pulse train portion, for example, superimposed thereon.

### CROSS-REFERENCE TO RELATED PATENT DOCUMENTS

This patent application is also related to a U.S. patent application, filed even date herewith, titled SYSTEM AND METHOD FOR ADAPTIVE ILLUMINATION IN A LIDAR SYSTEM (Attorney Docket No. 3867.591US1; Client Docket No. APD6571), naming Ronald A. Kapusta and Miles R. Bennett as inventors, the disclosure of which is hereby incorporated herein by reference, in its entirety, including its disclosure adjusting one or more parameters to vary the illumination output within at least one of the regions-of-interest (ROIs) in a field-of-view (FOV) and to adjust one or more corresponding receiver parameter(s).

### FIELD OF THE DISCLOSURE

This document pertains generally, but not by way of limitation, to systems for providing light detection and ranging (LIDAR).

### BACKGROUND

Pulse light detection and ranging (LIDAR) systems can calculate a distance to one or more objects in a field of view by measuring a time-of-flight of an optical LIDAR return signal received in response to one or more light pulses emitted by an optical transmitter. The LIDAR return signal must be detected in the presence of noise, such as from one or various noise sources.

### SUMMARY OF THE DISCLOSURE

This disclosure describes various techniques to encode a single light pulse with information that can provide the benefits of a single long pulse and a short, coded pulse train. For example, this disclosure describes techniques to generate a light pulse for transmission that has an optical intensity profile that includes a waveform having one or more relatively narrower pulses superimposed upon a relatively wider pulse. Thus, a hybrid pulse can be generated that includes both a wide pulse and a narrow pulse train portion, for example, superimposed thereon.

In some aspects, this disclosure is directed to a pulsed-mode illuminator system for specifying or adjusting an optical intensity profile of a light pulse, the illuminator system comprising a pulsed light source to emit a transmitted light pulse in response to an electrical illumination pulse control signal; and controller circuitry, electrically coupled to the light source, to provide to the light source the electrical illumination pulse control signal to generate via the light source a transmitted light pulse having an optical intensity profile that includes a waveform comprising one or more relatively narrower pulses superimposed upon a relatively wider pulse.

In some aspects, this disclosure is directed to a method for specifying or adjusting an optical intensity profile of a light pulse in a pulsed-mode illuminator system, the method comprising generating an electrical illumination pulse control signal to generate via a light source a transmitted light pulse having an optical intensity profile that includes a waveform comprising one or more relatively narrower pulses superimposed upon a relatively wider pulse; and transmitting the light pulse in response to the electrical illumination pulse control signal.

In some aspects, this disclosure is directed to a pulsed-mode illuminator system for specifying or adjusting an optical intensity profile of a light pulse, the illuminator system comprising means for generating an electrical illumination pulse control signal to generate via a light source a transmitted light pulse having an optical intensity profile that includes a waveform comprising one or more relatively narrower pulses superimposed upon a relatively wider pulse; and a pulsed light source to emit the transmitted light pulse in response to the electrical illumination pulse control signal.

This overview is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is an example of a LIDAR system that can implement various techniques of this disclosure.

FIG. 2 is a conceptual time domain diagram depicting an example of a light pulse having an optical intensity profile that includes a waveform having one or more relatively narrower pulses superimposed upon a relatively wider pulse.

FIG. 3 is a conceptual frequency domain diagram 300 depicting the light pulse of FIG. 2.

FIG. 4 is a conceptual diagram depicting an example of an optical intensity profile in the time domain that includes a waveform having one or more relatively narrower pulses superimposed upon a relatively wider pulse in accordance with various techniques of this disclosure.

FIG. 5 is a conceptual diagram depicting a narrow pulse train superimposed on a wide pulse based on the example of a waveform in FIG. 4.

FIG. 6 illustrates an example of a pulsed-mode illuminator system architecture and corresponding signal flow, such as for implementing a LIDAR system in accordance with various techniques of this disclosure.

FIG. 7 is a simplified circuit diagram of an example of a laser driver and a laser that can be used to implement various techniques of this disclosure.

FIGS. 8A-8D depict various example operating modes configurations of the laser driver circuit of FIG. 7 that can be used to generate various states of the narrower pulses superimposed upon a relatively wider pulse.

### DETAILED DESCRIPTION

The present inventors have recognized, among other things, that noise in a LIDAR system can have various sources and that some LIDAR system noise sources can be frequency dependent. For example, a transimpedance amplifier can be coupled to a photodetector to amplify an electrical signal based on the optical return LIDAR signal detected by and transduced into an electrical signal by the photodetector. Such a transimpedance amplifier can have a noise characteristic that increases with frequency, such that the transimpedance amplifier can be noisier at higher frequencies.

To accommodate such a transimpedance amplifier noise characteristic, a wider LIDAR transmit pulse can be used, having more energy concentrated at lower frequencies than a narrower LIDAR transmit pulse. But accurately determining a time-of-flight of the return LIDAR signal can be best accomplished using a narrower LIDAR transmit pulse, which has more energy concentrated at higher frequencies, at which the transimpedance amplifier can be noisy. For example, multiple narrow pulses can be combined close to one another to form a pulse train, e.g., where the time delay between the pulses in the pulse train is equal to or less than the time-of-flight for a pulse reflected by an object at the farthest distance measured. For interference mitigation purposes, the narrow pulses, e.g., forming a pulse train, can be encoded as a sequence.

Additionally, more distant objects are more easily detected using higher energy LIDAR transmit pulses, for example, wider or higher amplitude LIDAR transmit pulses. In a LIDAR system, range accuracy can be more important for closer objects than for distant objects.

This disclosure describes various techniques to encode a single light pulse with information that can provide the benefits of a single long pulse and a short, coded pulse train. For example, this disclosure describes techniques to generate a light pulse for transmission that has an optical intensity profile that includes a waveform having one or more relatively narrower pulses superimposed upon a relatively wider pulse. Thus, a hybrid pulse can be generated that includes both a wide pulse and a narrow pulse train portion, for example, superimposed thereon.

For distant objects, the wide pulse portion of the hybrid pulse of this disclosure can maximize detection range because high frequency noise can be filtered out without removing the low-frequency content contained in the wide pulse signal. For objects at closer range and with adequate signal-to-noise ratio (SNR), the narrow pulse portion of the hybrid pulse of this disclosure can be detectable above the noise floor, which can yield good range resolution and precision.

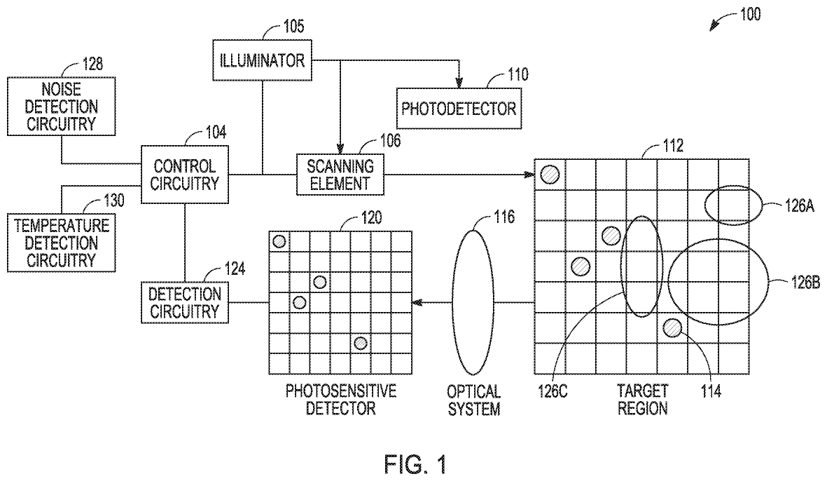

FIG. 1 shows an example of portions of a LIDAR system 100 that can implement various techniques of this disclosure. The LIDAR system 100 can operate in a pulsed-mode and can include control circuitry 104, an illuminator circuit 105, a scanning element 106, an optical system 116, a photosensitive detector 120, and detection circuitry 124. The control circuitry 104 can be connected to the illuminator circuit 105, the scanning element 106 and the detection circuitry 124. The photosensitive detector 120 can be connected to the detection circuitry 124.

During operation, the control circuitry 104 can provide instructions to the illuminator 105 and the scanning element 106, such as to cause the illuminator 105, e.g., a pulsed light source, to emit a light pulse towards the scanning element 106 and to cause the scanning element 106 to direct the light pulse towards the target region 112. In an example, the illuminator 105 can include a laser and the scanning element 106. The scanning element 106 can adjust an angle of the light pulse based on the received instructions from the control circuitry 104. The scanning element could be an electro-optic waveguide, a MEMS mirror, a mechanical mirror, an optical phased array, or any other optical scanning device.

The target region 112 can correspond to a field-of-view (FOV) of the optical system 116. The scanning element 106 can scan the light beam over the target region 112 in a series of scanned segments 114. The optical system 116 can receive at least a portion of the light beam from the target region 112 and can image the scanned segments 114 onto the photosensitive detector 120 (e.g., an array of avalanche photodiodes, single photon avalanche detectors, or p-i-n photodiodes; a CMOS sensor; or a charge-coupled device). The detection circuitry 124 can include, among other things, transimpedance amplifier circuitry to detect the return signal. The detection circuitry 124 can receive and process the image of the scanned points from the photosensitive detector 120, such as to form a frame.

In an example, the control circuitry 104 can select one or more regions-of-interest (ROIs) 126A-126C (referred to collectively in this disclosure as ROIs 126), where each ROI can be a subset of the FOV of the optical system and instruct the scanning element to scan over the ROI. As an alternative, the entire FOV may be scanned by the scanning element, and the illuminator 105 can vary its behavior when each of the ROIs is traversed. In an example, the detection circuitry 124 can include circuitry for digitizing the received image.

In some example configurations, the system 100 can include noise detection circuitry 128 to detect noise present in and/or near the system 100. Additionally or alternatively, the system 100 can include temperature detection circuitry 130 to detect an ambient temperature and/or a temperature of the system 100.

In an example, the LIDAR system 100 can be installed in an automobile, such as to facilitate a self-driving automobile. An FOV of the optical system 116 can be associated with the photosensitive detector 120, such as in which the optical system 116 images light onto the photosensitive detector 120. The photosensitive detector 120 can include and be divided into an array of detector pixels 121, and the optical system's FOV can be divided into an array of pixel FOVs with each pixel FOV of the optical system corresponding to a pixel of the photosensitive detector 120.

As mentioned above, the present inventors have recognized, among other things, that noise in a LIDAR system can have various sources. For example, a transimpedance amplifier in the detection circuitry 124 can have a noise characteristic that increases with frequency, such that the transimpedance amplifier can be noisier at higher frequencies.

To solve this problem, the present inventors have recognized that the pulsed-mode illuminator system 100 can specify or adjust an optical intensity profile of a light pulse such as to help at least one of noise performance, accuracy, or resolution. The control circuitry 104 can provide to the illuminator circuit 105, e.g., a pulsed light source, an electrical illumination pulse control signal to generate via the illuminator circuit 105 a transmitted light pulse having an optical intensity profile that includes a waveform having one or more relatively narrower pulses superimposed upon a relatively wider pulse. In this manner, the system 100 can encode a single pulse with information that can provide the benefits of a single wide pulse and a short, coded narrow pulse train. Thus, this disclosure describes, among other things, techniques to generate a hybrid pulse that includes both a wide pulse and, superimposed on the wide pulse, a narrow pulse train portion.

The techniques of this disclosure allow wide pulses to be used in a LIDAR transmitter, for example, without suffering from the drawbacks mentioned above that can occur with the use of wide pulses. By way of non-limiting examples, the techniques of this disclosure can be applicable for use in LIDAR systems with high capacitance photodetectors, such as LIDAR systems that use p-i-n photodiodes. The techniques of this disclosure can also be useful for LIDAR systems that use avalanche photodiodes (APDs), such as monostatic LIDAR systems, because the techniques can ease the constraint on the laser driver. In addition, lower voltage and/or higher inductance can be tolerated because the narrow pulse train components can typically be smaller in amplitude.

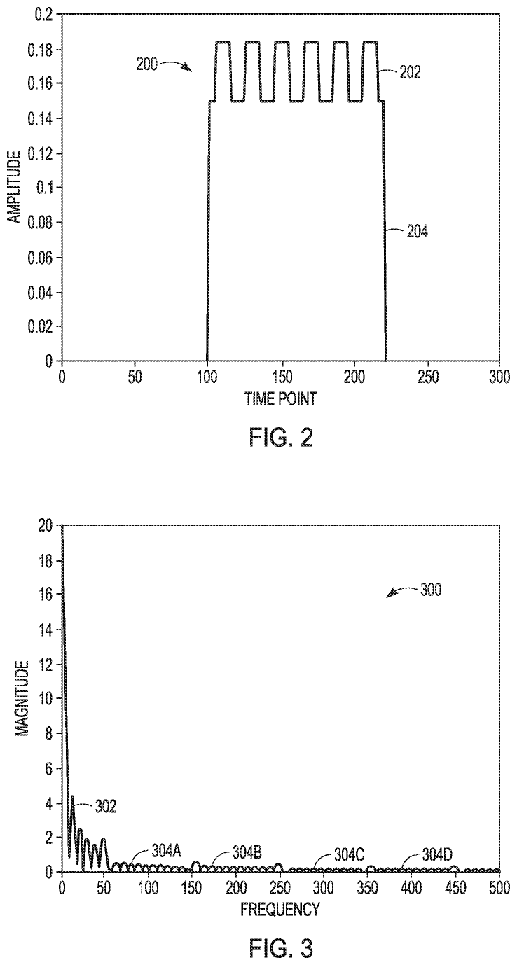

FIG. 2 is a conceptual time domain diagram depicting an example of a light pulse having an optical intensity profile that includes a waveform having one or more relatively narrower pulses superimposed upon a relatively wider pulse. The x-axis depicts time and the y-axis depicts amplitude.

As seen in FIG. 2, the light pulse 200 has narrower pulses 202, e.g., a pulse train, superimposed on a relatively wider pulse 204. The light pulse 200 can be considered a hybrid pulse because of the combination of the wide pulse 204 and the narrow pulses 202.

In the non-limiting conceptual diagram in FIG. 2, the pulse 200 has an amplitude of about 0.18 normalized units and the narrow pulses 202 have an amplitude of about 0.03 normalized units. As such, the narrow pulses 202 do not return to zero amplitude in FIG. 2. However, in some implementations, it can be desirable for the narrow pulses 202 to return to zero. Both configurations are considered within the scope of this disclosure.

In some example implementations, the relative contributions of the wide pulse portion 204 and the narrow pulse portion(s) 202 can be varied to emphasize maximizing detection range, range accuracy, range resolution, or interference mitigation. For example, additional narrow pulses 202 can be superimposed upon a wide pulse portion 204 to improve range resolution.

FIG. 3 is a conceptual frequency domain diagram 300 depicting the light pulse of FIG. 2. The x-axis depicts frequency and the y-axis depicts magnitude.

As seen in FIG. 3, the energy in the wide pulse portion 204 of the pulse 200 of FIG. 2 is concentrated at lower frequencies, as seen at 302. The energy in the narrow pulse portion 202 of the pulse 200 of FIG. 2 is concentrated at higher frequencies, as seen at 304A-304D, for example. Most of the signal content occurs at lower frequencies, but there is still significant high frequency signal content.

Using the same pulse (the hybrid pulse of this disclosure), a detection range can be maximized for distant objects using the wide pulse portion 204 of FIG. 2 (the narrow pulses 202 can be inconsequential) and, for closer objects where range accuracy and range resolution is desirable, the high frequency content from the narrow pulse portions 202 of FIG. 2 can be used. That is, assuming an adequate SNR, the high frequency content can extend above the noise floor thereby allowing the signal to be detected.

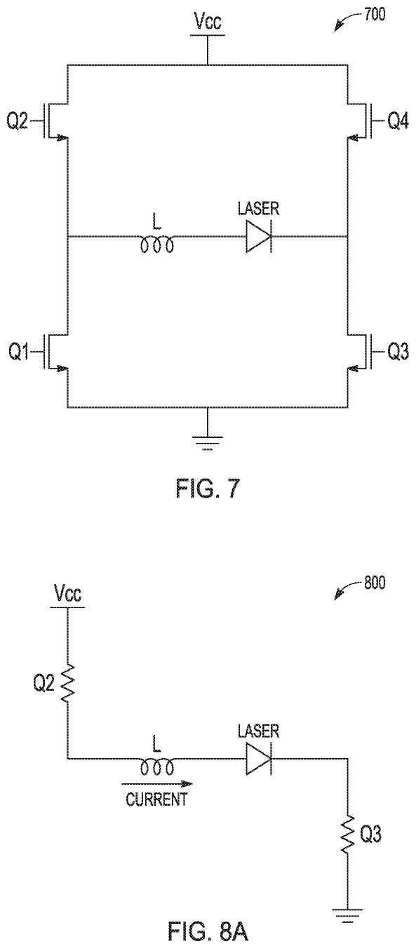

A pulsed laser driver circuit, such as circuit 700 of FIG. 7, can be part of the illuminator circuit 105 of FIG. 1 and can include, among other things, a high current driver to drive a laser diode. An inductor L can represent the parasitic inductance of the laser diode and any associated packaging.

A capacitor, e.g., a charge reservoir, can charge through a resistor. When the high current driver turns ON, the charge on the capacitor discharges through the inductor L and into the laser diode. When the capacitor C discharges, most of the supply voltage VCC is dropped across the inductor L.

Current through an inductance cannot change instantaneously and, as such, a current I through the inductor L increases with slope dI/dt=V/L. The laser driver circuit can control a turn-on characteristic resulting in a current increasing with slope dI/dt. The laser driver circuit can similarly control the turn-off characteristic resulting in a current decreasing with slope dI/dt. By using these configurations, a waveform can be generated to code information using +1 and −1, for example.

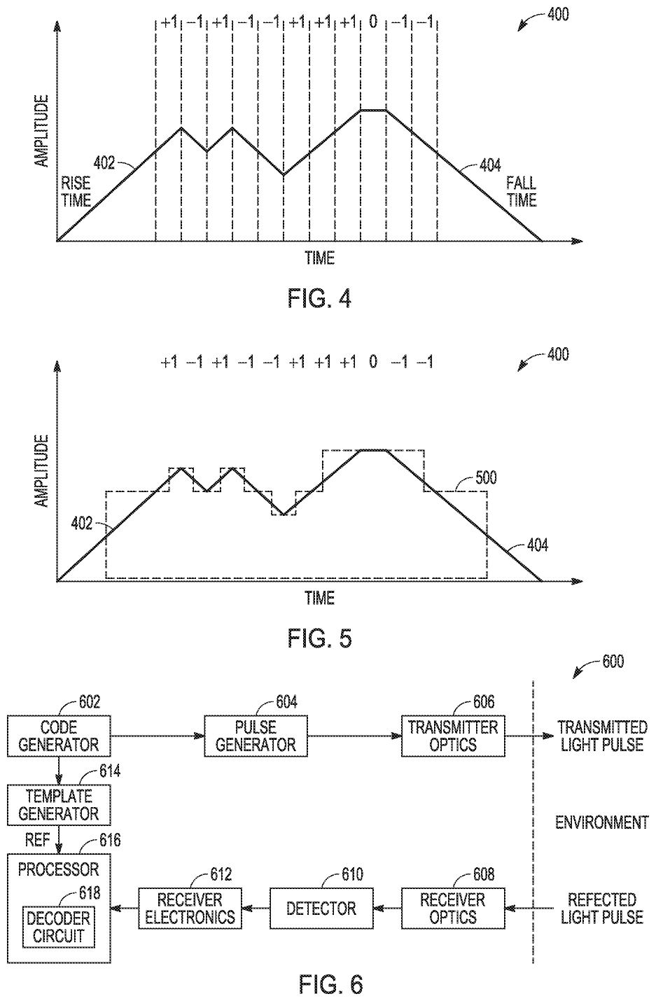

In some example configurations, the laser driver circuit can also have a constant current mode in which the slope remains steady or flat, neither increasing nor decreasing. By also using the steady-amplitude configuration, a waveform such as shown in FIG. 4 can be generated to code information using +1, 0, and −1, for example.

FIG. 4 is a conceptual diagram depicting an example of an optical intensity profile in the time domain that includes a waveform having one or more relatively narrower pulses superimposed upon a relatively wider pulse in accordance with various techniques of this disclosure. The x-axis represents time and the y-axis represents amplitude.

To establish the wide pulse portion, the waveform 400 can include a first ramp-up portion or rising portion 402 having a rise time and a last ramp-down portion or falling edge 404 having a fall time. Within the wide pulse portion, e.g., between portions 402, 404, a combination of one or more positively-sloped pulses (the portions labeled “+1”), e.g., increasing current or intensity, and negatively-sloped pulse (the portions labeled “−1”), e.g., decreasing current or intensity, can establish the narrow pulse(s) of the hybrid pulse. For example, the waveform 400 can include at least one rising edge (the portions labeled “+1”) or falling edge (the portions labeled “−1”) that is offset in time from the first rising edge 402 and from the last falling edge 404 of the transmitted light pulse.

In some example configurations, one or more steady-amplitude pulses (the portions labeled “0”), e.g., constant current or intensity, can be included in the waveform 400. The inclusion of steady-amplitude pulse(s) can allow additional pulse shape modification.

A control circuit, e.g., the control circuitry 104 of FIG. 1, can provide an electrical illumination pulse control signal to generate via a pulsed light source, e.g., the pulsed laser driver circuit 700 of FIG. 7, a transmitted light pulse having at least one narrower pulse that includes one or more of positively-sloped amplitude pulses, e.g., a first state, negatively-sloped amplitude pulses, e.g., a second state, and steady-amplitude pulses, e.g., a third state, superimposed upon a relatively wider pulse.

The illuminator system, e.g., system 100 of FIG. 1, can transmit a pulse during which the system switches between at least the first and second states at least four times, such as increase (positively-sloped amplitude), decrease (negatively-sloped amplitude), increase (positively-sloped amplitude), and decrease (negatively-sloped amplitude). In this manner, the illuminator system can transmit a pulse that is the superposition of a wider pulse and a sequence of narrow pulses, where the width of the wider pulse is equal to or greater than the duration of the narrow pulse sequence.

In some example configurations, the control circuit can adjust the wide pulse or the narrower pulses to encode information. For example, the control circuit can control the pulsed light source, e.g., the laser driver circuit of FIG. 7, to encode combinations of 1 and −1 and, in some cases 0, to encode information, e.g., for interference mitigation.

In some implementations, it can be desirable to vary a pulse characteristic, e.g., a pulse width, of either or both of the relatively wider pulse or the superimposed relatively narrower pulse(s). For example, pulse characteristics can be specified, e.g., fixed, or can be adaptively variable, e.g., in a random or pseudo-random manner. For example, Barker codes can be used to generate pseudo-random pulse characteristics.

Noise characteristics, e.g., of a transimpedance amplifier, can change over time. As such, it can be desirable to specify or adaptively vary a pulse characteristic, e.g., a pulse width, of either or both of the relatively wider pulse or the superimposed relatively narrower pulse(s) based at least in part on a noise present in or detected by the system, e.g., by noise detection circuit 128 of FIG. 1.

In addition, noise characteristics, e.g., of a transimpedance amplifier, can change over temperature. As such, it can be desirable to specify or adaptively vary a pulse characteristic, e.g., a pulse width, of either or both of the relatively wider pulse or the superimposed relatively narrower pulse(s) based at least in part on a temperature detected by the system, e.g., by temperature detection circuitry 130 of FIG. 1.

As mentioned above, for distant objects, the wide pulse portion of the hybrid pulse can maximize detection range because high frequency noise can be filtered out without removing the low-frequency content contained in the wide pulse signal. For objects at closer range and with adequate signal-to-noise ratio (SNR), the higher frequency content associated with the narrow pulse portion of the hybrid pulse can be detectable above the noise floor, which can yield good range resolution. Once an object is detected by the illuminator system, e.g., system 100 of FIG. 1, it can be desirable to specify or adaptively vary a pulse characteristic, e.g., a pulse width, of either or both of the relatively wider pulse or the superimposed relatively narrower pulse(s) based at least in part on a distance to the object detected by the system.

For example, when the transmitted light pulse is directed toward a relatively closer object than when the transmitted light pulse is directed toward a relatively farther object for an object detected relatively far away, a pulse characteristic can be specified or varied to a higher frequency characteristic, which can improve range resolution. As another example, when the transmitted light pulse is directed toward a relatively farther object than when the transmitted light pulse is directed toward a relatively closer object, a pulse characteristic can be specified or varied to a higher energy characteristic, e.g., lower frequency characteristic, which can maximize detection range.

In some example implementations, it can be desirable to specify or adaptively vary a pulse characteristic, e.g., a pulse width, of either or both of the relatively wider pulse or the superimposed relatively narrower pulse(s) based at least in part upon a scanned location within a field of view (FOV). For example, a first pulse characteristic can be used to scan a first ROI of an FOV, e.g., ROI 126A of FOV 112 in FIG. 1, and a second pulse characteristic can be used to scan a second ROI of the FOV, e.g., ROI 126B of FOV 112 in FIG. 1. Additional information can be found in related U.S. patent application, filed even date herewith, titled SYSTEM AND METHOD FOR ADAPTIVE ILLUMINATION IN A LIDAR SYSTEM (Attorney Docket No. 3867.591US1; Client Docket No. APD 6571), naming Ronald A. Kapusta and Miles R. Bennett as inventors, the disclosure of which is hereby incorporated herein by reference, in its entirety, including its disclosure adjusting one or more parameters to vary the illumination output within at least one of the regions-of-interest (ROIs) in a field-of-view (FOV) and to adjust one or more corresponding receiver parameter(s).

In some example implementations, the narrow pulse components can be smaller in magnitude than the wide pulse component, which can provide an emphasis on long range detection. At shorter range, with greater signal strength and thus higher SNR, even a small narrow pulse component can be adequate to achieve good range resolution.

FIG. 5 is a conceptual diagram depicting an example of a narrow pulse train superimposed on a wide pulse based on the waveform shown in FIG. 4. The x-axis represents time and the y-axis represents amplitude.

FIG. 5 shows how the waveform 400 of FIG. 4 can be considered to be a hybrid pulse having a profile 500 that includes narrow pulses, e.g., a narrow pulse train, superimposed on a wide pulse defined between a first rising edge 402 and a last falling edge 404.

FIG. 6 illustrates an example of a pulsed-mode illuminator system architecture and corresponding signal flow, such as for implementing a LIDAR system 600 in accordance with various techniques of this disclosure. The top half of the diagram corresponds to the generation and transmission of a light pulse and the bottom half of the diagram corresponds to the reception and decoding of a reflected light pulse.

A code generator circuit 602 can generate a sequence of numbers that describe the optical intensity profile, e.g., the shape, of the light pulse to be transmitted. A valid code of numbers can include a sequence where each element can be drawn from the set {−1, +1}), e.g., for two-level signaling, or the set {−1, 0, +1}, e.g., for three-level signaling. Once the code generator circuit 602 has generated a code, e.g. [+1, +1, +1, −1, +1, −1, +1, −1, −1, −1], a pulse generator circuit 604 can transform the code into a laser waveform, such as shown conceptually in FIG. 4. For example, the pulse generator circuit 604 can convert −1 into a falling edge, 0 into a flat edge, and +1 into a rising edge.

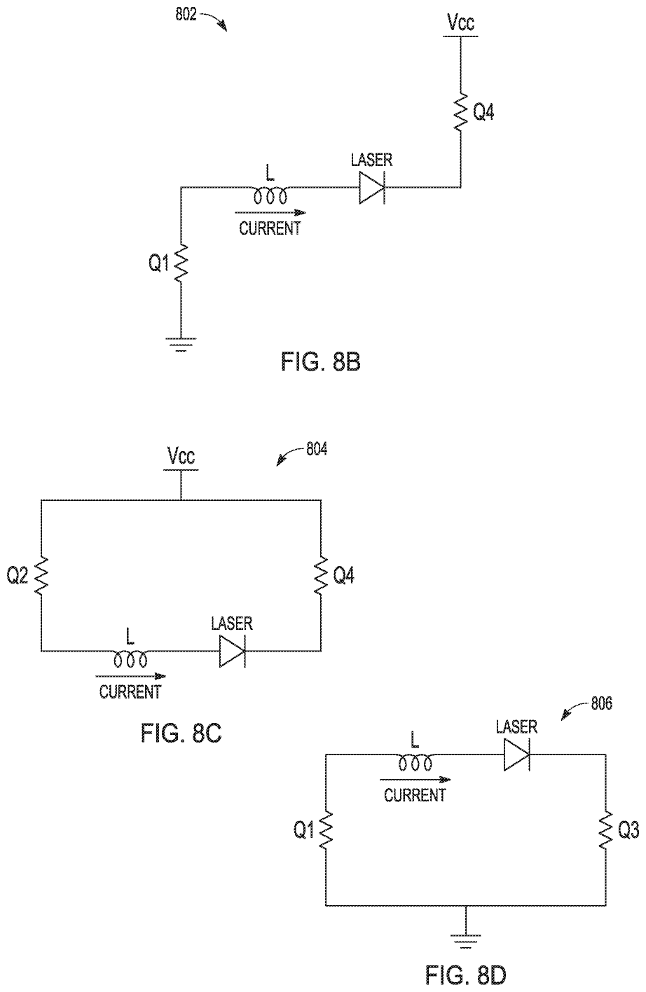

The pulse generator circuit 602 can include a laser driver, a laser, and various associated peripheral components. The pulse generator block 602 is described in more detail with respect to FIG. 7 and FIGS. 8A-8D, e.g., H-bridge laser driver and laser. Finally, a transmitter optics circuit 606 can include various components to transmit the light pulse into the environment.

If an object is present in the environment at the current location in the field-of-view, then the return signal (the reflected light pulse) can be modeled as an attenuated and time delayed version of the transmitted signal. A receiver optic circuit 608 can collect light from the environment and focus the collected light onto a detector circuit 610.

The detector circuit 610 can include a photodetector (e.g. a photodiode) that can be sensitive to light having the same wavelength as the light generated by the pulse generator circuit 604. The detector circuit 610 can receive light in response to the transmitted light pulse and can convert the received light into an electrical return signal, which can then be processed by a receiver electronics circuit 612.

The receiver electronics circuit 612 can amplify, filter, and digitize the return signal. The receiver electronics circuit 612 can include, among other things, a transimpedance amplifier (TIA), analog-to-digital converter (ADC), and associated peripheral electronics (e.g., power supplies, voltage references, clock generators, etc.).

Finally, the location of the object(s) in the environment can be determined from the time delay of the digitized return signal relative to a template waveform, e.g., a reference signal. A template generator circuit 614 can generate a template waveform based on the output of the code generator circuit 602 (e.g. [+1, +1, +1, −1, +1, −1, +1, −1, −1, −1]) and estimates of the rising slope and falling slope of the pulse generator.

A processor circuit 616, such as a digital signal processor (DSP) or field programmable gate array (FPGA), can receive the digitized return signal SIG and analyze the return signal with respect to the received template waveform via reference signal REF to determine a distance to the object. The processor circuit 616 can include a decoder circuit 618, e.g., a decoding filter, configured to process the return signal SIG to detect or use the information encoded onto the relatively narrower pulses of the transmitted light pulse.

FIG. 7 is a simplified circuit diagram of an example of a laser driver and a laser that can be used to implement various techniques of this disclosure. In some example configurations, the laser driver and laser circuit 700 can be arranged in an H-bridge configuration, such as shown in FIG. 7. The H-bridge configuration can include switching elements, such as transistors Q1-Q4 that a control circuit, e.g., the pulse generator circuit 604 of FIG. 6 or the control circuitry 104 of FIG. 1, can selectively control, e.g., turn ON or OFF, to control a flow of current through an inductor L to the laser. By controlling the flow of current to the laser, the laser driver and laser circuit 700 can generate the states of the narrower pulses superimposed upon a relatively wider pulse described above.

FIGS. 8A-8D depict various example operating modes of the laser driver circuit of FIG. 7 that can be used to generate various states of the narrower pulses superimposed upon a relatively wider pulse. In FIGS. 8A-8D, the switching elements Q1-Q4 of FIG. 7, e.g., transistors, that have been turned ON (assuming depletion mode transistors) are represented by resistors.

In FIG. 8A, a circuit configuration 800 is shown that can generate amplitude pulses having positively-sloped pulses (rising edge, pulse code of +1), e.g., a first state or operating mode. As seen in FIG. 8A, the transistors Q1 and Q4 (of FIG. 7) have been turned OFF and the transistor Q2 and Q3 have been turned ON thereby allowing an increasing current to flow from the supply voltage VCC through the inductor L to the laser to generate positively-sloped pulses.

In FIG. 8B, a circuit configuration 802 is shown that can generate amplitude pulses having negatively-sloped pulses (falling edge, pulse code of −1), e.g., a second state. As seen in FIG. 8B, the transistors Q2 and Q3 (of FIG. 7) have been turned OFF and the transistor Q1 and Q4 have been turned ON, which reverses the polarity of the source voltage applied to the laser and allows a decreasing current to flow through the inductor L to the laser to generate negatively-sloped amplitude pulses.

In FIG. 8C, a circuit configuration 804 is shown that can generate amplitude pulses having steady-amplitude pulses (flat edge, pulse code of 0), e.g., a third state. As seen in FIG. 8C, the transistors Q1 and Q3 (of FIG. 7) have been turned OFF and the transistor Q2 and Q4 have been turned ON. As such, there is no voltage applied across the laser, resulting in a constant current mode in which the slope neither increases nor decreases.

In FIG. 8D, another circuit configuration 806 is shown that can generate amplitude pulses having steady-amplitude pulses (flat edge, pulse code of 0), e.g., a fourth state. As seen in FIG. 8D, the transistors Q2 and Q4 (of FIG. 7) have been turned OFF and the transistor Q1 and Q3 have been turned ON. As such, there is no voltage applied across the laser, resulting in a constant current mode in which the slope neither increases nor decreases.

By using various techniques described above, the same pulse (the hybrid pulse of this disclosure), can maximize a detection range for distant objects using the wide pulse portion and, for closer objects where range accuracy and range resolution is desirable, the high frequency content from the narrow pulse portions can be used. In addition, the hybrid pulse can be shaped, such as to mitigate the effects of interfering pulses.

### Notes

Each of the non-limiting aspects or examples described herein may stand on its own or may be combined in various permutations or combinations with one or more of the other examples.

The above detailed description includes references to the accompanying drawings, which form a part of the detailed description. The drawings show, by way of illustration, specific embodiments in which the invention may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein may be machine or computer-implemented at least in part. Some examples may include a computer-readable medium or machine-readable medium encoded with instructions operable to configure an electronic device to perform methods as described in the above examples. An implementation of such methods may include code, such as microcode, assembly language code, a higher-level language code, or the like. Such code may include computer readable instructions for performing various methods. The code may form portions of computer program products. Further, in an example, the code may be tangibly stored on one or more volatile, non-transitory, or non-volatile tangible computer-readable media, such as during execution or at other times. Examples of these tangible computer-readable media may include, but are not limited to, hard disks, removable magnetic disks, removable optical disks (e.g., compact discs and digital video discs), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments may be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments may be combined with each other in various combinations or permutations. The scope of the invention should be determined with reference to the appended claims, along with the full scope of equivalents to which such claims are entitled.

The claimed invention is:

1. A pulsed-mode illuminator system for specifying or adjusting an optical intensity profile of a light pulse, the illuminator system comprising:
a pulsed light source to emit a transmitted light pulse in response to an electrical illumination pulse control signal; and
controller circuitry, electrically coupled to the light source, to provide to the light source the electrical illumination pulse control signal to generate via the light source a transmitted light pulse having an optical intensity profile that includes a waveform comprising one or more relatively narrower pulses superimposed upon a relatively wider pulse.

2. The illuminator system of claim 1, in which the controller circuitry is configured to provide the electrical illumination pulse control signal to generate via the light source a transmitted light pulse having the relatively narrower pulses including at least one pulse comprising at least one of a positively-sloped or a negatively-sloped pulse.

3. The illuminator system of claim 2, in which the controller circuitry is configured to provide the electrical illumination pulse control signal to generate via the light source a transmitted light pulse having the relatively narrower pulses further including at least one steady-amplitude pulse.

4. The illuminator system of claim 1, in which the controller circuitry is configured to provide the relatively narrower pulses adjusted to encode information.

5. The illuminator system of claim 4, in combination with:
a receiver including:
a photodetector, configured to receive light including in response to the transmitted light pulse for transducing into an electrical return signal; and
a decoder circuit, configured to process the electrical return signal to detect or use the information encoded onto the relatively narrower pulses of the transmitted light pulse.

6. The illuminator system of claim 1, in which the controller circuitry is configured to provide to the light source the electrical illumination pulse control signal to generate via the light source a transmitted light pulse having a light intensity waveform that includes at least one rising or falling edge that is offset in time from a first rising edge and from a last falling edge of the transmitted light pulse.

7. The illuminator system of claim 1, in which a pulse characteristic of at least one of the relatively wider pulse or the one or more superimposed relatively narrower pulses is specifiable or adaptively variable based at least in part on a noise present in or detected by the illuminator system.

8. The illuminator system of claim 1, in which a pulse characteristic of at least one of the relatively wider pulse or the one or more superimposed relatively narrower pulses is specifiable or adaptively variable in a random or pseudo-random manner.

9. The illuminator system of claim 1, further comprising a temperature detector, and in which a pulse characteristic of at least one of the relatively wider pulse and the one or more superimposed relatively narrower pulses is specifiable or adaptively variable based at least in part on a temperature detected by the temperature detector.

10. The illuminator system of claim 1, in which a pulse characteristic of at least one of the relatively wider pulse and the one or more superimposed relatively narrower pulses is specifiable or adaptively variable based at least in part on a distance to an object detected by the illuminator system.

11. The illuminator system of claim 10, in which the pulse characteristic is specified or varied to a higher frequency characteristic when the transmitted light pulse is directed toward a relatively closer object than when the transmitted light pulse is directed toward a relatively farther object.

12. The illuminator system of claim 10, in which the pulse characteristic is specified or varied to a higher energy characteristic when the transmitted light pulse is directed toward a relatively farther object than when the transmitted light pulse is directed toward a relatively closer object.

13. The illuminator system of claim 1, in which transmitted light pulses are scanned across a field of view, and in which the pulse characteristic of the transmitted light pulse is specifiable or variable based at least in part upon a scanned location within the field of view.

14. A method for specifying or adjusting an optical intensity profile of a light pulse in a pulsed-mode illuminator system, the method comprising:
generating an electrical illumination pulse control signal to generate via a light source a transmitted light pulse having an optical intensity profile that includes a waveform comprising one or more relatively narrower pulses superimposed upon a relatively wider pulse; and
transmitting the light pulse in response to the electrical illumination pulse control signal.

15. The method of claim 14, wherein the waveform comprises at least one of a positively-sloped or a negatively-sloped pulse.

16. The method of claim 15, wherein the waveform further comprises at least one steady-amplitude pulse.

17. The method of claim 14, comprising:
encoding information using the relatively narrower pulses.

18. The method of claim 14, comprising:
specifying or adaptively varying a pulse characteristic of at least one of the relatively wider pulse or the one or more superimposed relatively narrower pulses based at least in part on a noise present in or detected by the illuminator system.

19. A pulsed-mode illuminator system for specifying or adjusting an optical intensity profile of a light pulse, the illuminator system comprising:
means for generating an electrical illumination pulse control signal to generate via a light source a transmitted light pulse having an optical intensity profile that includes a waveform comprising one or more relatively narrower pulses superimposed upon a relatively wider pulse; and
a pulsed light source to emit the transmitted light pulse in response to the electrical illumination pulse control signal.

20. The illuminator system of claim 19, wherein the means for generating an electrical illumination pulse control signal includes:
means for generating at least one of a positively-sloped or a negatively-sloped pulse.
